(19) United States
(12) Patent Application Publication
(10) Pub. No.: US 2018/0218673 A1
(43) Pub. Date: Aug. 2, 2018

(54) ORGANIC LIGHT EMITTING DIODE (OLED) PIXEL COMPENSATION CIRCUITS AND OLED DEVICES

(71) Applicant: Wuhan China Star Optoelectronics Technology Co., Ltd., Wuhan, Hubei (CN)

(72) Inventor: Jun LI, Shenzhen, Guangdong (CN)

(73) Assignee: Wuhan China Star Optoelectronics Technology Co., Ltd., Wuhan, Hubei (CN)

(21) Appl. No.: 15/504,022

(22) PCT Filed: Dec. 28, 2016
(86) PCT No.: PCT/CN2016/112645

§ 371 Date: Feb. 15, 2017

(30) Foreign Application Priority Data
Dec. 26, 2016 (CN) 201611218908.5

(51) Int. Cl. G09G 3/3225; H01L 27/32

(52) U.S. Cl. CPC G09G 3/3225; G09G 2320/0233; H01L 27/3211; H01L 27/3244

(57) ABSTRACT

An OLED pixel compensation circuit for driving OLEDs includes a demux and a plurality of sub-pixel compensation circuits. The demux includes a plurality of transistors, a number of the transistors is the same with the number of the sub-pixel compensation circuits, and each of the transistors is configured to provide a data voltage to the corresponding sub-pixel compensation circuit. Any one of the transistors and the corresponding sub-pixel compensation circuit is connected in accordance with: a first connecting end of any one of the transistors receives the a data voltage and a control end of any one of the transistors receives enable signals such that a second connecting end of any of the transistors connects to the corresponding sub-pixel compensation circuit when any one of the transistors is turned on by an effective level of the enable signals received by the control end.

### BACKGROUND OF THE INVENTION

### 1. Field of the Invention

The present disclosure relates to display technology, and more particularly to an organic light emitting diode (OLED) pixel compensation circuit and an OLED device.

### 2. Discussion of the Related Art

With respect to Active-matrix organic light emitting diode (AMOLED) devices, the lighting brightness of each of the OLED is determined by a driving current generated by a driving circuit, and the driving current may be expressed in accordance with the equation:

I_{OLED}=k(V_{gs}−Vₜₕ)²;

Wherein k represents a current enlarging coefficient relating to attributes and dimensions of the driving transistor, V_{gs} represent a voltage gap between a gate and a source or between the gate and a drain of the driving transistor, and Vₜₕ represents a threshold voltage of the driving transistor.

When the AMOLED device displays an image frame, the threshold voltage (Vₜₕ) may drift and the driving current (I_{OLED}) may change, which results in a lighting brightness of the OLED change, and also the display uniformity of the displayed image frame. In addition, under a high-temperature and high-voltage condition, the drifting amplitude of the threshold voltage (Vₜₕ) of the driving transistor may be different, which results in different display brightness. Such brightness difference may cause blur issue.

### SUMMARY

The present disclosure relates to an OLED pixel compensation circuit to solve the non-uniform brightness issue of the conventional OLED device.

In one aspect, an organic light emitting diode (OLED) pixel compensation circuit for driving OLEDs includes: a demultiplexer (demux) and a plurality of sub-pixel compensation circuits; wherein the demux includes a plurality of transistors, a number of the transistors is the same with the number of the sub-pixel compensation circuits, and each of the transistors is configured to provide a data voltage to the corresponding sub-pixel compensation circuit; wherein any one of the transistors and the corresponding sub-pixel compensation circuit is connected in accordance with: a first connecting end of any one of the transistors receives the a data voltage and a control end of any one of the transistors receives enable signals such that a second connecting end of any of the transistors connects to the corresponding sub-pixel compensation circuit when any one of the transistors is turned on by an effective level of the enable signals received by the control end so as to provide the data voltage to the corresponding sub-pixel compensation circuit.

Wherein the corresponding sub-pixel compensation circuit includes a first transistor (T1), a second transistor (T2), a third transistor (T3), a fourth transistor (T4), a fifth transistor (T5), a sixth transistor (T6), a storage capacitance, and the OLED; wherein the control end of the first transistor (T1) is reset when the fourth transistor (T4) is turned on, the storage capacitance is charged when the second transistor (T2) and the third transistor (T3) are turned, a supply voltage and the voltage of the storage capacitance (Cst) are overlapped to the control end of the first transistor (T1) when the fifth transistor (T5) and the sixth transistor (T6) are turned on so as to drive the OLED.

Wherein the first connecting end of the fifth transistor (T5) receives the supply voltage, the second connecting end of the fifth transistor (T5) connects to the first end of the first transistor (T1) and the first connecting end of the second transistor (T2), the control end of the fifth transistor (T5) receives emitting signals, the second connecting end of the second transistor (T2) connects to the second connecting end of any one of the transistors, the control end of the second transistor (T2) receives second scanning signals, the first end of the storage capacitance connects to the supply voltage, the second end of the storage capacitance connects to the first connecting end of the fourth transistor, the control end of the first transistor (T1), and the first connecting end of the third transistor (T3); the second connecting end of the fourth transistor (T4) connects to a reset voltage, the control end of the fourth transistor (T4) receives first scanning signals, the second connecting end of the third transistor (T3) connects to the second connecting end of the first transistor (T1) and the first connecting end of the sixth transistor (T6), the control end of the third transistor (T3) receives second scanning signals, the second connecting end of the sixth transistor (T6) connects to the first end of the OLED, the control end of the sixth transistor (T6) receives the emitting signals, and the second end of the OLED is grounded.

Wherein the first transistor (T1) is turned on according to a voltage difference between the first connecting end and the control end, the second transistor (T2) is turned on when the control end of the second transistor (T2) receives an effective level of the second scanning signals (scan (n)), the third transistor (T3) is turned on when the control end of the third transistor (T3) receives the effective level of the second scanning signals (scan (n)), the fourth transistor (T4) is turned on when the control end of the fourth transistor (T4) receives an effective level of the first scanning signals (Xscan(n)), the fifth transistor (T5) is turned on when the control end of the fifth transistor (T5) receives the effective level of the emitting signals (em(n)), the sixth transistor (T6) is turned on when the control end of the sixth transistor (T6) receives the effective level of the emitting signals (em(n)).

Wherein the effective level of the first scanning signals (Xscan(n)) is one of a high level and a low level, and a non-effective level of the first scanning signals (Xscan(n)) is one of the high level and the low level, the effective level of the second scanning signals (scan(n)) is one of the high level and the low level, and the non-effective level of the second scanning signals (scan(n)) is one of the high level and the low level, the effective level of the emitting signals (em(n)) is one of the high level and the low level, and the non-effective level of the emitting signals (em(n)) is one of the high level and the low level.

Wherein the effective level of the data voltage ends before the effective level of the enable signals.

Wherein the effective level of the data voltage begins together with the effective level of the enable signals, or the effective level of the data voltage begins earlier than the effective level of the enable signals.

Wherein the sub-pixel compensation circuits includes a red sub-pixel compensation circuit, a green sub-pixel compensation circuit, and a blue sub-pixel compensation circuit, wherein a duration of the effective level of the enable signals (En) received by the control end of the transistors of the green sub-pixel compensation circuit corresponding to the demux is configured to be the longest one, and the duration of the effective level of the enable signals (En) receive by the control end of the transistors of the blue sub-pixel compensation circuit corresponding to the demux is configured to be the shortest one.

In another aspect, an OLED display device includes the above OLED pixel compensation circuit.

With such configuration, the demux is adopted to provide the data signals to the OLED pixels, which greatly reduces the number of the channels of the data channels and the manufacturing cost of the integrated circuit.

### BRIEF DESCRIPTION OF THE DRAWINGS

FIG. 1 is a circuit diagram of the OLED pixel compensation circuit in accordance with one embodiment.

FIG. 2 is a timing diagram of the OLED pixel compensation circuit in accordance with one embodiment.

FIG. 3 is a timing diagram of the OLED pixel compensation circuit in accordance with another embodiment.

### DETAILED DESCRIPTION OF THE EMBODIMENTS

Embodiments of the invention will now be described more fully hereinafter with reference to the accompanying drawings, in which embodiments of the invention are shown.

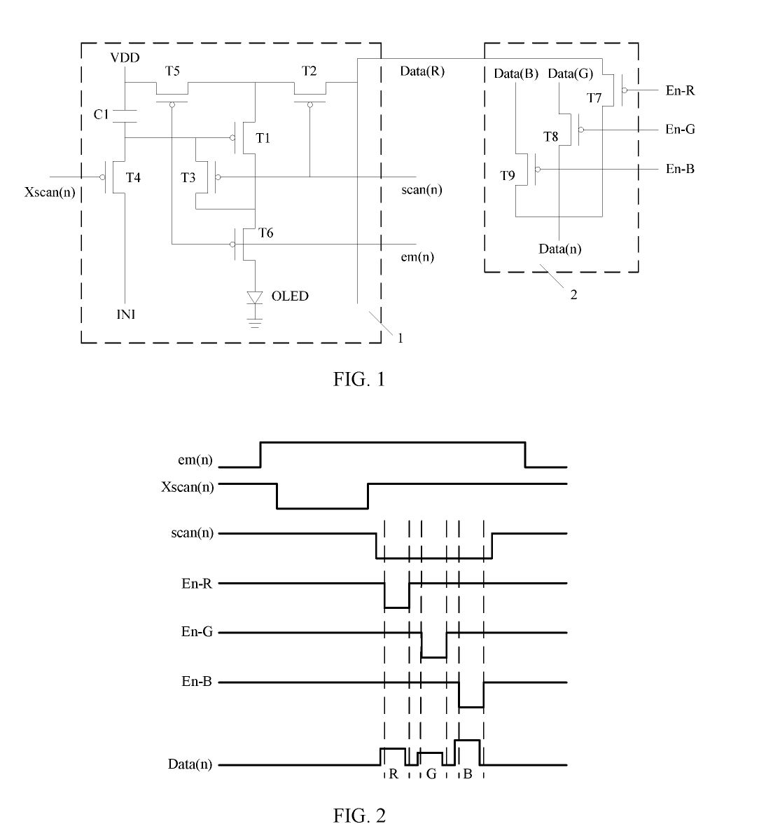

FIG. 1 is a circuit diagram of the OLED pixel compensation circuit in accordance with one embodiment.

The OLED pixel compensation circuit drives the organic light emitting diode (OLED) to emit lights. It can be understood that the OLED pixel may include a plurality of sub-pixels, including red sub-pixels (R), green sub-pixels (G), and blue sub-pixels (B). In an example, the red sub-pixel of the OLED pixel compensation circuit illustrates the circuit structure and the operational principle of any one of the compensation circuit of the red sub-pixel in the n-th column.

As shown in FIG. 1, the OLED pixel compensation circuit includes a compensation circuit 1 of the red sub-pixel and a demultiplexer (demux) 2. The compensation circuit 1 includes a first transistor (T1), a second transistor (T2), a third transistor (T3), a fourth transistor (T4), a fifth transistor (T5), a sixth transistor (T6), a storage capacitor (C1), and an OLED.

A first connecting end of the fifth transistor (T5) connects to a supply voltage (VDD), a second connecting end of the fifth transistor (T5) connects to a first end of the first transistor (T1) and a first connecting end of the second transistor (T2), a control end of the fifth transistor (T5) receives emitting signals (em(n)), a second connecting end of the second transistor (T2) connects to an output end Data (R) of the demux, a control end of the second transistor (T2) receives second scanning signals (scan (n)), an input end of the demux receives a data voltage (Data (n)), a first end of the storage capacitor (C1) connects to the supply voltage (VDD), a second end of the storage capacitor (C1) connects to a first connecting end of the fourth transistor (T4), a control end of the first transistor (T1), and a first connecting end of the third transistor (T3), a second connecting end of the fourth transistor (T4) connects to a reset voltage (INI), a control end of the fourth transistor (T4) receives first scanning signals (Xscan(n)), a second connecting end of the third transistor (T3) connects to the second electrically connect of the first transistor (T1) and a first connecting end of the sixth transistor (T6), a control end of the third transistor (T3) receives the second scanning signals (scan (n)), a second connecting end of the sixth transistor (T6) connects to a first end of the OLED, a control end of the sixth transistor (T6) receives the signals (em(n)), and a second end of the OLED is grounded.

The demux includes a plurality of transistors, and a number of the transistors is the same with the number of the sub-pixels of the OLED pixels. The first connecting end of each of the transistor connects to an input end of the demux, the control end of each of the transistors respectively receives enable signals (En), the second connecting end of each of the transistors operates as the output end of the demux connecting to the second connecting end of the second transistor (T2) of the corresponding compensation circuit 1 of the OLED sub-pixel.

Preferably, as shown in FIG. 1, the OLED pixel includes the red sub-pixels (R), the green sub-pixels (G), and the blue sub-pixels (B). The demux includes a seventh transistor (T7), an eighth transistor (T8), and a ninth transistor (T9). For instance, a control end of the seventh transistor (T7) receives first enable signals (En-R), a first connecting end of the seventh transistor (T7) receives the data voltage of the n-th column, a second connecting end of the seventh transistor (T7) connects to the second connecting end of the second transistor (T2) of the compensation circuit of the OLED red sub-pixel, that is, the compensation circuit 1 in FIG. 1. A control end of the eighth transistor (T8) receives second enable signals (En-G), a first connecting end of the eighth transistor (T8) receives the data voltage of the n-th column, a second connecting end of the eighth transistor (T8) connects to the second connecting end of the second transistor (T2) of the compensation circuit of the OLED green sub-pixel, a control end of the ninth transistor (T9) receives third enable signals (En-B), a first connecting end of the ninth transistor (T9) receives the data voltage of the n-th column, a second connecting end of the ninth transistor (T9) connects to the second connecting end of the second transistor (T2) of the compensation circuit of the OLED blue sub-pixel.

The first transistor (T1) is turned on according to a voltage difference between the first connecting end and the control end, the second transistor (T2) is turned on when the control end of the second transistor (T2) receives an effective level of the second scanning signals (scan (n)), the third transistor (T3) is turned on when the control end of the third transistor (T3) receives the effective level of the second scanning signals (scan (n)), the fourth transistor (T4) is turned on when the control end of the fourth transistor (T4) receives an effective level of the first scanning signals (Xscan(n)), the fifth transistor (T5) is turned on when the control end of the fifth transistor (T5) receives the effective level of the emitting signals (em(n)), the sixth transistor (T6) is turned on when the control end of the sixth transistor (T6) receives the effective level of the emitting signals (em(n)), the seventh transistor (T7) is turned on when the control end of the seventh transistor (T7) receives the effective level of the first enable signals (En-R), the eighth transistor (T8) is turned on when the control end of the eighth transistor (T8) receives the effective level of the second enable signals (En-G), and the ninth transistor (T9) is turned on when the control end of the ninth transistor (T9) receives the effective level of the third enable signals (En-B).

In an example, the effective level of the first scanning signals (Xscan(n)) may be one of a high level and a low level, and a non-effective level of the first scanning signals (Xscan(n)) may be one of the high level and the low level, the effective level of the second scanning signals (scan(n)) may be one of the high level and the low level, and the non-effective level of the second scanning signals (scan(n)) may be one of the high level and the low level, the effective level of the emitting signals (em(n)) may be one of the high level and the low level, and the non-effective level of the emitting signals (em(n)) may be one of the high level and the low level, the effective level of the first enable signals (En-R) may be one of the high level and the low level, and the non-effective level of the first enable signals (En-R) may be one of the high level and the low level, the effective level of the second enable signals (En-G) may be one of the high level and the low level, and the non-effective level of the second enable signals (En-G) may be one of the high level and the low level, the effective level of the third enable signals (En-B) may be one of the high level and the low level, and the non-effective level of the third enable signals (En-B) may be one of the high level and the low level.

It can be understood that the circuit structure and the operational principle of the compensation circuit of the green sub-pixel and the blue sub-pixel are the same with that of the red sub-pixel, and thus the detailed descriptions are omitted hereinafter.

FIG. 2 is a timing diagram of the OLED pixel compensation circuit in accordance with one embodiment.

In an example, the effective level of the second scanning signals (scan (n)) is the low level, the non-effective level of the first scanning signals (Xscan(n)) is the high level, the effective level of the second scanning signals (scan (n)) is the low level, the non-effective level of the second scanning signals (scan (n)) is the high level, the effective level of the emitting signals (em(n)) is the low level, and the non-effective level of the emitting signals (em(n)) is the high level. The first transistor (T1), the second transistor (T2), the third transistor (T3), the fourth transistor (T4), the fifth transistor (T5), and the sixth transistor (T6) are PMOS transistors.

The operational process of the OLED pixel compensation circuit in FIG. 1 includes four phases:

The first phase is a reset phase: When the fourth transistor (T4) is turned on by the low level of the second scanning signals (scan (n)), the storage capacitor (C1) discharges, and the level of the control end of the first transistor (T1) is reset to be an initial voltage (INI).

The second phase is a pre-charge phase: When the second transistor (T2) and the third transistor (T3) are turned on in response to the low level of the second scanning signals (scan (n)). At the moment, the level of the data signals of the previous column, i.e., the residual data voltage of the (n−1)-th column, is greater than the level of the control end of the first transistor (T1), that is, Vdata(n−1) is greater than the initial voltage (INI). Thus, first transistor (T1) is turned on, the data signals of the previous column charge the storage capacitor (C1) via the second transistor (T2), the level of the control end of the first transistor (T1) is increased. At this moment, the threshold voltage (Vth) of the first transistor (T1) is captured. When the level of the control end of the first transistor (T1) is increased to be Vdata(n−1)-Vth, i.e., the difference between the residual data voltage Vdata(n−1) of the (n−1)-th column and the threshold voltage (Vth), the first transistor (T1) is turned off.

The third phase is a compensation phase: The first connecting end of the seventh transistor (T7) of the demux receives the data signals of the red sub-pixel in the n-th column, after a predetermined period or when the first connecting end of the seventh transistor (T7) receives the data signals of the n-th red sub-pixel, the seventh transistor (T7) is turned on in response to the low level of the first enable signals (En-R). At this moment, the data voltage of the data voltage of the red sub-pixel in the n-th column is greater than the level of the control end of the first transistor (T1), that is, Vdata(n) is greater than Vdata(n−1)-Vth, the first transistor (T1) is turned on again such that the data signals of the red sub-pixel in the n-th column charges the storage capacitor (C1) via the second transistor (T2). In addition, before the effective level of the first enable signals (En-R), the data voltage of the red sub-pixel in the n-th column is pulled down to a predetermined voltage. Preferably, the predetermined voltage is lower than the lowest data voltage among all of the data voltages.

The fourth phase is a lighting phase: The fifth transistor (T5) and the sixth transistor (T6) are turned on in response to the low level of the emitting signals (em(n)). At this moment, the first transistor (T1) is also in an on state. Under the circumstance, the supply voltage (VDD) and the voltage of the storage capacitor (C1) are overlapped to the control end of the first transistor (T1) to drive the OLED to emit lights.

It can be understood that, the first transistor (T1), the second transistor (T2), the third transistor (T3), the fourth transistor (T4), the fifth transistor (T5), and the sixth transistor (T6) are PMOS transistors, wherein the first transistor (T1) may be a driving TFT transistor, and the second transistor (T2), the third transistor (T3), the fourth transistor (T4), the fifth transistor (T5), and the sixth transistor (T6) are switch TFT transistors. The compensation circuit of the red sub-pixel in FIG. 1 is only one example. Persons skilled in the art may configure different types of the transistors and the connection relationships as long as the OLED sub-pixel may be driven. Before the effective level of the enable signals, the current data voltage is pulled down to the predetermined voltage so as to realize the control toward the compensation circuit of the sub-pixels by the demux.

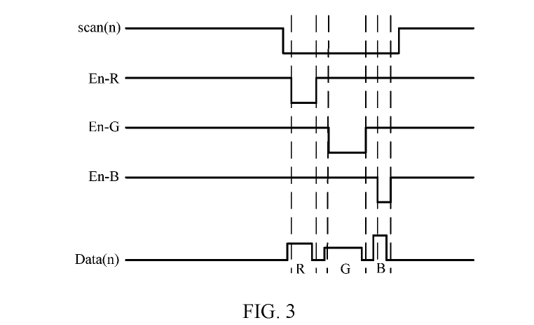

FIG. 3 is a timing diagram of the OLED pixel compensation circuit in accordance with another embodiment.

As user's sensitivity toward the green color, red color, and blue color are from the greatest levels to the smallest levels. When the error conditions are the same, the errors with respect to the green sub-pixel (G) may be easily detected, that is, the deviation of the grayscale of the green sub-pixel is the greatest one. In the embodiments, the demux is adopted to transmit the data signals, which reduces the writing time and the time required for capturing the threshold voltage (Vth) with respect to the red sub-pixel (R), the green sub-pixel (G), and the blue sub-pixel (B). Usually, when the writing time is longer, the precision of the data is greater. Correspondingly, the grayscale deviation is smaller. Thus, in one embodiment, the duration of the effective level of the enable signals (En) received by the control end of the transistors of the compensation circuit of the green sub-pixel corresponding to the demux may be configured to be the longest one, and the duration of the effective level of the enable signals (En) receive by the control end of the transistors of the compensation circuit of the blue sub-pixel corresponding to the demux may be configured to be the shortest one.

In an example, with respect to the demux in FIG. 1, the duration of the effective level of the second enable signals (En-G) received by the control end of the eighth transistor (T8) of the compensation circuit of the green sub-pixel may be configured to be the longest one, the duration of the effective level of the third enable signals (En-B) received by the control end of the ninth transistor (T9) of the compensation circuit of the blue sub-pixel may be configured to be the shortest one,

the duration of the effective level of the first enable signals (En-R) received by the control end of the seventh transistor (T7) of the compensation circuit of red green sub-pixel may be configured to be between the durations of the above two.

As shown in FIG. 3, the duration of the effective level of the data signals of the green sub-pixel in the n-th column is the longest one, the duration of the effective level of the data signals of the red sub-pixel in the n-th column is the second longest one, and the duration of the effective level of the data signals of blue green sub-pixel in the n-th column is the shortest one.

In view of the above, the demux is adopted to provide the data signals to the OLED pixels, which greatly reduces the number of the channels of the data channels and the manufacturing cost of the integrated circuit.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. An organic light emitting diode (OLED) pixel compensation circuit for driving OLEDs, comprising:
a demultiplexer (demux) and a plurality of sub-pixel compensation circuits;
wherein the demux comprises a plurality of transistors, a number of the transistors is the same with the number of the sub-pixel compensation circuits, and each of the transistors is configured to provide a data voltage to the corresponding sub-pixel compensation circuit;
wherein any one of the transistors and the corresponding sub-pixel compensation circuit is connected in accordance with:
a first connecting end of any one of the transistors receives the data voltage and a control end of any one of the transistors receives enable signals such that a second connecting end of any of the transistors connects to the corresponding sub-pixel compensation circuit when any one of the transistors is turned on by an effective level of the enable signals received by the control end so as to provide the data voltage to the corresponding sub-pixel compensation circuit.

2. The OLED pixel compensation circuit as claimed in claim 1, wherein the corresponding sub-pixel compensation circuit comprises a first transistor (T1), a second transistor (T2), a third transistor (T3), a fourth transistor (T4), a fifth transistor (T5), a sixth transistor (T6), a storage capacitance, and the OLED;
wherein the control end of the first transistor (T1) is reset when the fourth transistor (T4) is turned on, the storage capacitance is charged when the second transistor (T2) and the third transistor (T3) are turned, a supply voltage and the voltage of the storage capacitance (Cst) are overlapped to the control end of the first transistor (T1) when the fifth transistor (T5) and the sixth transistor (T6) are turned on so as to drive the OLED.

3. The OLED pixel compensation circuit as claimed in claim 2, wherein the first connecting end of the fifth transistor (T5) receives the supply voltage, the second connecting end of the fifth transistor (T5) connects to the first end of the first transistor (T1) and the first connecting end of the second transistor (T2), the control end of the fifth transistor (T5) receives emitting signals, the second connecting end of the second transistor (T2) connects to the second connecting end of any one of the transistors, the control end of the second transistor (T2) receives second scanning signals, the first end of the storage capacitance connects to the supply voltage, the second end of the storage capacitance connects to the first connecting end of the fourth transistor, the control end of the first transistor (T1), and the first connecting end of the third transistor (T3); the second connecting end of the fourth transistor (T4) connects to a reset voltage, the control end of the fourth transistor (T4) receives first scanning signals, the second connecting end of the third transistor (T3) connects to the second connecting end of the first transistor (T1) and the first connecting end of the sixth transistor (T6), the control end of the third transistor (T3) receives second scanning signals, the second connecting end of the sixth transistor (T6) connects to the first end of the OLED, the control end of the sixth transistor (T6) receives the emitting signals, and the second end of the OLED is grounded.

4. The OLED pixel compensation circuit as claimed in claim 1, wherein the first transistor (T1) is turned on according to a voltage difference between the first connecting end and the control end, the second transistor (T2) is turned on when the control end of the second transistor (T2) receives an effective level of the second scanning signals (scan (n)), the third transistor (T3) is turned on when the control end of the third transistor (T3) receives the effective level of the second scanning signals (scan (n)), the fourth transistor (T4) is turned on when the control end of the fourth transistor (T4) receives an effective level of the first scanning signals (Xscan(n)), the fifth transistor (T5) is turned on when the control end of the fifth transistor (T5) receives the effective level of the emitting signals (em(n)), the sixth transistor (T6) is turned on when the control end of the sixth transistor (T6) receives the effective level of the emitting signals (em(n)).

5. The OLED pixel compensation circuit as claimed in claim 4, wherein the effective level of the first scanning signals (Xscan(n)) is one of a high level and a low level, and a non-effective level of the first scanning signals (Xscan(n)) is one of the high level and the low level, the effective level of the second scanning signals (scan(n)) is one of the high level and the low level, and the non-effective level of the second scanning signals (scan(n)) is one of the high level and the low level, the effective level of the emitting signals (em(n)) is one of the high level and the low level, and the non-effective level of the emitting signals (em(n)) is one of the high level and the low level.

6. The OLED pixel compensation circuit as claimed in claim 1, wherein the effective level of the data voltage ends before the effective level of the enable signals.

7. The OLED pixel compensation circuit as claimed in claim 6, wherein the effective level of the data voltage begins together with the effective level of the enable signals, or the effective level of the data voltage begins earlier than the effective level of the enable signals.

8. The OLED pixel compensation circuit as claimed in claim 1, wherein the sub-pixel compensation circuits comprises a red sub-pixel compensation circuit, a green sub-pixel compensation circuit, and a blue sub-pixel compensation circuit, wherein a duration of the effective level of the enable signals (En) received by the control end of the transistors of the green sub-pixel compensation circuit corresponding to the demux is configured to be the longest one, and the duration of the effective level of the enable signals (En) receive by the control end of the transistors of the blue sub-pixel compensation circuit corresponding to the demux is configured to be the shortest one.

9. A OLED display device comprises the OLED pixel compensation circuit as claimed in claim 1.
